(19) United States
(12) Patent Application Publication
(10) Pub. No.: US 2004/0157430 A1
(43) Pub. Date: Aug. 12, 2004

(54) Methods and apparatus for processing semiconductor wafers with plasma processing chambers in a wafer track environment

(75) Inventor: Robert P. Mandal, Saratoga, CA (US)

Correspondence Address: Michael Bernadicou, BLAKELY, SOKOLOFF, TAYLOR & ZAFMAN LLP, 12400 Wilshire Boulevard, Seventh Floor, Los Angeles, CA, 90025, US

(73) Assignee: ASML Netherlands B.V., Veldhoven (NL)

(21) Appl. No.: 10/359,853

(22) Filed: Feb. 7, 2003

(51) Int. Cl. H01L 21/4763; H01L 21/469; H01L 21/31

(52) U.S. Cl. 438/636; 438/952

(57) ABSTRACT

A plasma chamber for performing semiconductor wafer processing within a wafer track system. The processing chamber may be configured as a thermal stack module within a wafer track cell for exposing a semiconductor wafer surface to a processing plasma. A showerhead electrode and wafer chuck assembly may be positioned within the processing chamber for effecting plasma-enhanced processing of the semiconductor wafer. Various types of supply gas sources may be in fluid communication with the showerhead electrode to provide a gaseous mixture that forms the desired plasma. The flow of gases may be regulated by a controller and a series of gas control valves to form and introduce the preselected gaseous mixture into the processing chamber as plasma that is exposed to the semiconductor wafer surface. The preselected gaseous mixture may be formulated for different semiconductor wafer processing operations such as surface prime treatment and bottom anti-reflective coating (BARC) deposition.

### FIELD OF THE INVENTION

The invention generally relates to plasma processing during semiconductor manufacturing processes. More specifically, the invention is related to surface prime treatment and the deposition of thin-film materials with plasma processing chambers within a photolithographic wafer track system.

### BACKGROUND

Many photolithographic cluster systems used in the manufacturing of semiconductor integrated circuits currently incorporate an integrated wafer track and photolithographic or stepper system. Various modules within the wafer track system perform certain functions including the coating of an underlying semiconductor wafer substrate with photosensitive films referred to as photoresists or resists. The resist coated wafers can be transported subsequently to an adjoining stepper system designed for submicron-feature pattern exposures, and then returned subsequently to the wafer track system for development of the exposed pattern. It has been observed that the presence of moisture on the substrate surface adversely affects the adhesive qualities of the deposited resist film. Furthermore, when the resist coated wafer is transported to the stepper and pattern exposed during the photolithography process, other problems persist during this step in the process such as optical interference caused by the reflection of light passing back through the film from the underlying substrate. These problems can be addressed in part through the application of certain advantageous thin-films or coatings during wafer processing.

In order to increase the adhesion of a photoresist film relative to a semiconductor wafer substrate, its surface may be exposed to hydrophobic treatment with surface primers such as hexamethyldisilazane (HMDS). The HMDS treatment of a substrate surface is intended to increase the adhesion between the resist film and the wafer surface. HMDS is often supplied as vapor along with gaseous agents such as nitrogen into a process chamber during a process referred to as vapor prime (VP) surface treatment. VP with HMDS has been long employed to condition and chemically treat wafers to provide hydrophobic surfaces. HMDS can be stored in a liquefied state and contained within a remotely located tank that is in fluid communication with the process chamber. A bubbler may be connected to the tank which supplies nitrogen or other carrier gases for the HMDS liquid. The HMDS liquid thus vaporizes and is mixed with the carrier gas which are together supplied to the VP process chamber through selected conduits that are regulated by flow meters and valve assemblies. A semiconductor wafer within the process chamber can be initially heated to a predetermined temperature such as 130° C. before exposure to incoming HMDS vapor. The process chamber may be eventually exhausted afterwards following VP surface treatment.

HMDS has a boiling point of 125° C. and is a secondary amine with the chemical structure Si(CH₃)₃—NH—Si(CH₃) ₃. It reacts with hydrophilic surfaces, predominately silanol groups (—Si—O—H) on the surface of oxides, thereby esterifying the silanol groups to form a trimethyldisiloxane, —Si—O—Si(CH₃) ₃, which is hydrophobic. A silyl amine is produced as a by-product of this reaction. The relative health hazards presented by the use of HMDS and other effective VP chemicals are well documented and generally accepted. HMDS nevertheless persists as a preferable VP agent over alternative chemicals in automated wafer tracks, and is among those toxic substances approved under current safety and health standards.

Although the HMDS surface prime treatment is employed in virtually all present day wafer tracks, it suffers from several significant drawbacks. For example, HMDS is a highly toxic substance that requires special procedures and precautions in its chemical handling and effluent waste disposal. The efficacy of transporting HMDS and controlling interaction with a wafer surface can be problematic. Proton acceptors such as HMDS are generally a hazard to deep UV photolithography. Deep UV photoresists often employ acid catalysis or chemical amplification for high quantum efficiency. Proton acceptors, most notably ammonia, amines, and substituted amines, “poison” deep UV photoresists by locally extinguishing catalysis, primarily at the surfaces of photoresist films, which can partially affect or completely inhibit pattern development. Finally, traces of stray HMDS can coat stepper lenses over time which impairs its operability. The elimination of HMDS from wafer track systems is thus desirable and would simultaneously eliminate the aforementioned hazards and performance limitations during vapor prime treatment of wafer surfaces.

The semiconductor process further involves photo-imaging processes following surface prime treatment and photoresist coating procedures. These photolithographic processes occur within the stepper system and ordinarily involve the projection of light onto a photoresist surface to create an imaged pattern. The photoresist for selected unexposed regions can then be selectively removed and receive additional material(s) as desired. It has been observed however that light can propagate through the photoresist film and reflect off the substrate surface back through the photoresist. This reflected light can interfere with other light waves propagating through the photoresist, and can reduce the quality and precision of the image that is to be transferred. A particular region of the photoresist may therefore be exposed non-uniformly, which can affect its subsequent removal during the highly selective processing steps. Additionally, the light reflected from the substrate surface can scatter and inadvertently expose unintended portions of photoresist which also impair accurate pattern development. The appreciable reflection of actinic radiation from this resist film/wafer surface interface during pattern exposure has been observed to significantly degrade submicron-pattern exposure results. Ultraviolet reflectivities generally increase toward shorter wavelengths, which becomes increasingly problematic as exposure wavelengths decrease from 248 nm to 193 nm to 157 nm in the relentless progression towards finer integrated circuit feature dimensions.

Some of the problems associated with reflected light during the photo-imaging process can be controlled with anti-reflective coatings. Anti-reflective coatings absorb various wavelengths of radiation and are typically applied as a layer in between the substrate surface and the photoresist. These coatings inhibit the reflected light from passing through the photoresist which would otherwise affect the imaging process. For example, a variety of bottom anti-reflective coatings (BARC) are commonly used that absorb radiation reflected from the substrate surface during photo-imaging operations. BARC deposition is typically applied by either organic film spin-casting or inorganic film plasma-enhanced chemical vapor deposition (PECVD). Organic BARC spin-on films tend to be relatively expensive materials and can be difficult to manage in its application. These films generally require a low-viscosity liquid that cannot be universally applied to all substrate surfaces. Moreover, these and other available organic spin-on treatments can have difficulty in adequately covering substrate surfaces with a substantially contoured topography. Meanwhile, PECVD BARC films tend to provide substantially better submicron-feature definition than spin-on alternatives. These inorganic PECVD BARC films, which are deposited using a relatively expensive separate tool, often require further plasma-treatment however with oxygen after film deposition to prevent detrimental effects on the photoresist.

There is a need for a more ecological and comprehensive solution to performing surface prime treatment and BARC deposition.

### SUMMARY OF THE INVENTION

The invention provides methods and apparatus for performing semiconductor processing with plasma process chambers in a wafer track environment. Various aspects of the invention can be appreciated individually or collectively as an opportunity to improve wafer track performance and convenience by utilizing integrated plasma process modules which enhance its value of ownership.

It is an object of the invention to provide plasma processing chambers within a wafer track system for promoting substrate surface reactions. In a preferable embodiment of the invention, a processing chamber is selected to receive a surface prime plasma. The plasma may enter the chamber to effect various treatments that improve the adhesive characteristics of the substrate surface and photoresist coatings subsequently deposited thereon. These plasma process chambers provide wafer surface prime alternatives that can replace costly and hazardous HMDS vapor prime modules to create hydrophobic substrate surfaces. Some of the advantages provided by the invention include elimination of HMDS from the wafer track environment during hydrophobic wafer surface treatment. An optional process formulation for wafer surface prime treatments herein may include plasmas generated from a gaseous composition comprised of helium, and relatively low concentrations of methane and hydrogen.

Another aspect of the invention provides methods and apparatus for improved BARC deposition using of plasma process chambers. The plasma-enhanced chemical vapor deposition (PECVD) of organic BARC materials described herein can replace spin-on BARC process modules ordinarily used with wafer track systems. The formulations and processes provided in accordance with the invention can also eliminate the need for added post-deposition steps such as a hard bake and oxygen plasma treatment, which are typically required with inorganic BARC materials. A preferable process gas formulation for organic BARC deposition may have a composition comprised of acetylene, allene, and carbon dioxide. These and other selected gases can be controllably introduced into the plasma processing chambers herein with conventional mass flow controllers to generate coatings with customized dial-in anti-reflection properties. Such conformal coatings can be applied separately or in combination with other wafer processing treatment depending upon desired characteristics and requirements.

The plasma processing formulations provided in accordance with yet another aspect of the invention may supply various environmentally-friendly gaseous materials into a common wafer track plasma chamber to prime wafer substrate surfaces and/or deposit anti-reflective coatings. The plasma prime treatment and anti-reflective coating process can be carried out within the same processing modules described herein, and may be integrated into thermal processing stacks within wafer track systems. Various sets of gaseous chemicals with predetermined chemical ratios can be conveniently delivered to plasma process chambers using conventional mass flow controllers. A surface prime formulation can be prepared and introduced into the plasma chambers herein for surface treatment of a semiconductor wafer. Within the same plasma chamber, another set of gases for BARC deposition or other coatings can be formulated and introduced without movement of the semiconductor wafer to yet another wafer track module. These space-saving and time-saving plasma processing modules can be integrated within the wafer track environment at a reduced cost and are capable of supporting multiple wafer processing functions.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### BRIEF DESCRIPTION OF THE FIGURES

The illustrations included within this specification describe advantages and features of the invention. It shall be understood that similar or like reference numerals and characters within the figures may designate the same or like features of the invention. It should be further noted that the illustrations provided herein are not necessarily drawn to scale.

FIG. 1 is an overall illustration of a wafer track system layout.

FIG. 2 is a simplified cross-sectional view of a plasma processing chamber that may be configured in accordance with various aspects of the invention for the surface prime treatment of wafer substrate surfaces and plasma deposition of anti-reflective coatings and/or other processing materials.

FIGS. 3 and 4 describe plasma processing methods provided in accordance with another aspect of the invention.

### DETAILED DESCRIPTION OF THE INVENTION

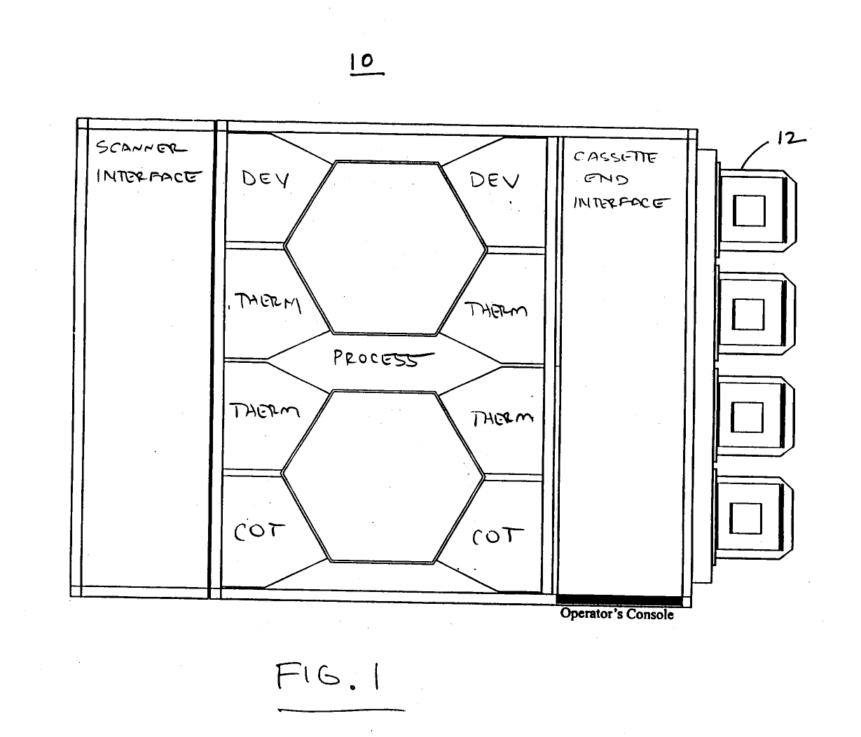

The invention herein may be applied to semiconductor processing equipment such as the wafer track system generally described in FIG. 1. The wafer track system 10 may include basically three sections: a cassette end interface section, a scanner interface section, and a process section. The cassette end interface section includes apparatus to transfer wafers from cassettes in which they are stored to the track system 10 and, conversely, from the track system back to cassettes following processing. The scanner interface section may be considered another transition area that accommodates equipment for transferring wafers between the track system 10 and photolithographic apparatus. Meanwhile, the process section of a wafer track basically includes stacks of wafer processing modules such as resist coating spin modules, bake/chill modules and resist developing spin modules. As shown in the system layout of FIG. 1, various process stacks within a wafer track may be arranged in an organized manner or optimal configuration to realize certain benefits and wafer handling efficiencies. For example, two or more process stations or “cells” may be configured within the process section having stacks of processing modules selected for resist coat (COT) and develop processes (DEV). Stacks of thermal modules (THERM) may also be included for heating and cooling wafers having heat exchange apparatus such as bake/chill plates. The process stations as shown in FIG. 1 may include a pair of photoresist coat sections (COT) or stacks of processing modules for applying resist coating onto wafers, and a pair of developing sections (DEV) with modules for developing a patterned resist-coated wafer. The wafers may be delivered and transported within the track system 10 between process stations using a series of robotic arms or other wafer handling apparatus according to a desired program or set of instructions in accordance with a predetermined order of processing.

A semiconductor wafer treatment process involves a highly organized set of procedures. Wafers can be initially fed into the wafer track from one or more cassettes stored locally at a cassette end station. As shown in the top view floor plan of FIG. 1, a series of wafer cassettes 12 can be arranged in a set of four distinct columns supported on a cassette-mounted table. A wafer carrying robot may gain access to a desired cassette in order to transfer wafers from and to selected process modules within the wafer track system in response to commands received from a controller (not shown). Before forming a photoresist film layer onto a wafer substrate, the wafer may be first transferred to a priming module where its surface can be thermally and/or chemically treated to remove the presence of moisture and to assure a hydrophobic surface. The wafer may then be cooled with thermal devices such as a chill plate, and then conveyed to a coating unit where a photoresist polymer is distributed evenly onto the wafer surface. The photoresist-coated wafer may be subsequently transferred to a heating unit or bake plate in order to heat and convert the photoresist polymer into a stable film. Upon completion of the heating step, the processed wafer may be cooled and either conveyed to a cassette for storage, or as in many instances, transferred directly to adjoining stepper apparatus through a stepper or scanner interface. The photoresist coating or film on the wafer is then exposed to a circuit pattern by a applicable photolithographic techniques within the stepper apparatus. After exposure of the stable film, the wafer can be transferred back to the track system 10 and heated in a bake module to set the circuit pattern onto the film. The wafer may be then cooled in a chill module, and transferred to a develop module. In the develop module, a solution is applied onto the film to develop a portion of the film, and then a rinse solution is applied thereafter onto the wafer in order to remove developer solution from the surface of the wafer. The wafer may be thermally treated in a bake module afterwards, cooled in a chill module, and then returned to a cassette 12 for storage. Variations of these steps and their order of operation may be modified to accomplish desired semiconductor wafer treatment.

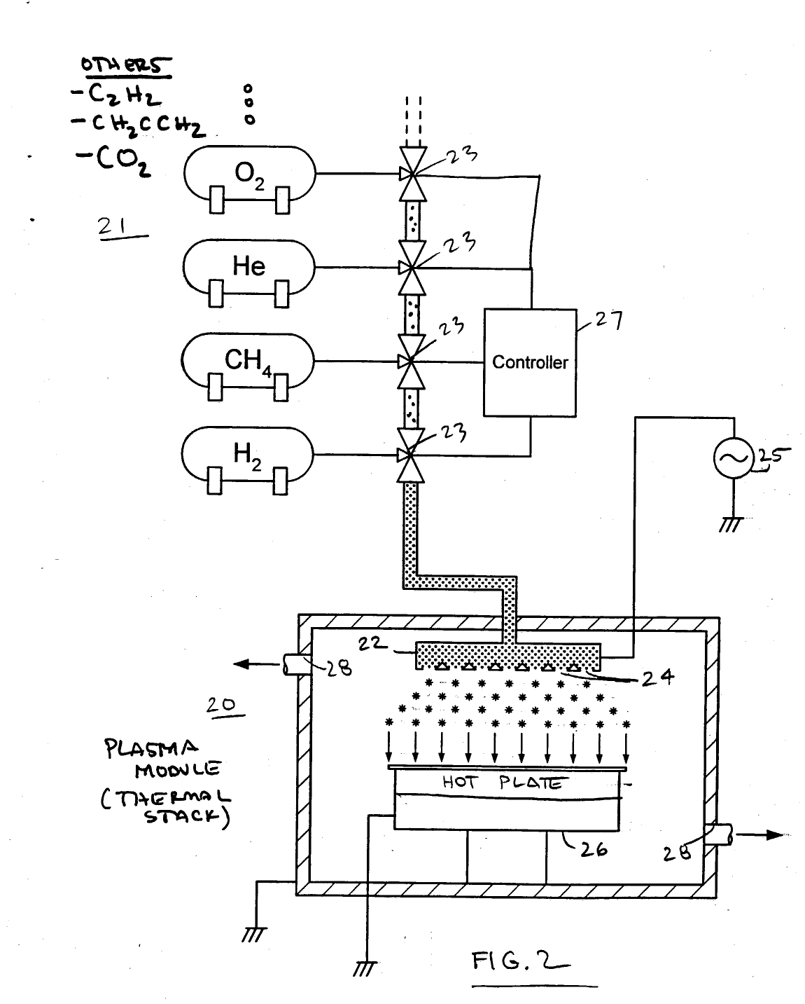

The plasma processing chambers provided in accordance with the invention can be integrated within wafer track systems. FIG. 2 describes a plasma processing chamber that can be installed in a stack of modules within a wafer track system. The chamber can be selected to perform single or multiple functions such as wafer surface prime treatment and/or film depositions, including bottom anti-reflection coatings (BARC). In accordance with this aspect of the invention, ionized gases are produced locally or remotely by exposing selected gas formulations to a high-frequency electrical discharge. The ionic species may then chemically react with an exposed surface area to deposit thin-material layers or to alter the characteristics of a substrate surface as with hydrophobic surface treatments described further herein.

Plasma assisted or enhanced processing is a technique used for various applications including etching and thin-film deposition. Plasma-enhanced chemical vapor deposition (PECVD) is often selected for conformally depositing thin layers of dielectrics, aluminum, copper, and other materials. The plasma used in plasma-enhanced processes can be generated either remotely or locally. Remotely generated plasma is produced by plasma-generating devices that are located external to a processing reactor. The resultant plasma is guided into a process chamber, and interacts with a semiconductor wafer therein for various desired fabrication or surface treatment processes. Locally generated plasma however is produced by a nearby plasma-generating charged electrode within or adjacent to the process chamber upon exposure to suitable process gases. Conventional plasma processing reactors for etch and deposition applications usually employ 13.56 MHz plasmas, 2.5 GHz remote plasmas, or a combination of these and other plasmas generated at high frequencies. In a reactor configured for local plasma generation, a plasma generating radio-frequency power source can be electrically connected to a conductive wafer holding device referred to as a wafer susceptor or chuck. The radio-frequency power allows the chuck and wafer to produce a radio-frequency plasma discharge proximate to a wafer surface. The plasma medium interacts with the semiconductor wafer surface and drives a desired fabrication process such as a wafer etch or thin-layer deposition. Alternatively, a showerhead assembly can be positioned opposite and parallel to the wafer and a similarly-sized chuck in other systems used for injecting the plasma-generating gas or gas mixtures into the process chamber. This particular plasma processing chamber design may be referred to as a parallel-plate configuration in view of the relatively parallel and appropriately-sized chuck and showerhead. Other plasma reactor configurations selected in accordance with the invention may include a showerhead assembly connected to a plasma-generating radio-frequency power source, while the chuck or reactor walls are connected to ground.

As shown in FIG. 2, a variety of selected processing gas formulations can be introduced into the plasma processing chamber 20 through a showerhead reactor assembly. The showerhead dispenser 22 may serve as a plasma electrode and may be precisely designed to engender high area deposited film thickness uniformity. A plurality of orifices or perforations 24 may be formed in the showerhead to dispense reactant gases. The showerhead electrode may be electrically connected as shown to a high frequency power source 25 selected at 400 KHz and 1300 W. In addition, a chuck electrode 26 may be positioned below the shower electrode 22 and connected to ground. The showerhead 22 and the chuck electrode 26 thus collectively form a parallel plate plasma generating circuit to ionize selected gas formulations described herein. The plasma processing chamber 20 may include various exhaust or vacuum ports 28 to evacuate gaseous species within the chamber as known by those of ordinary skill in the art. Other locally or remotely generated plasma reactors can be selected and modified in accordance with the invention to generate desired plasma species for substrate surface treatment and thin-layer deposition.

Furthermore, the process chemicals selected for application with the invention are preferably easy-to-handle compressed gases that are commercially available. The regulation and transport of these gases into the plasma processing chambers described herein can be accurately controlled through a series of conduits and mass flow controllers or valves. A gas supply control panel 27 may regulate a variety of gases 21 to be employed for wafer surface prime treatment, for organic BARC deposition, or for both and other wafer surface treatments and processing. Selected coatings or thin-films may be deposited using formulated gaseous mixtures that can provide customized dial-in anti-reflection properties. It shall be noted that some of the embodiments of the invention herein that are configured to carry out methods for BARC deposition may include a chamber cleaning step after the wafer is removed from the deposition chamber following film deposition procedures.

The plasma processing chambers herein may be modified and configured in a variety of ways to effect desired substrate surface treatment and thin-layer deposition. Some examples of optional process variables may include various high frequency ranges selected to generate the plasmas herein such as 400 kHz, 2.0 MHz, 13.56 MHz and other frequencies. The power supplied to the showerhead assemblies or other plasma generating equipment used to carry out the invention may also be selected to provide output ranging from approximately 20-1000 W for 200 mm wafer processing chambers, or higher for chambers configured for 300 mm wafers. Similarly, the diameter of a showerhead reactor may be determined by the size of the wafers to be processed for either batch or single-wafer processing. For certain applications, it may be also desirable to heat a substrate wafer on a hot plate within a thermal module in the wafer track system to a preselected temperature falling within various ranges such as from about 100-400° C. The distance or spacing between the showerhead and wafer may be also selected as desired ranging from about 5-20 mm. This height is an important parameter for the plasma chamber designs, which in turn alters the chamber volume and surface-to-volume ratio for a particular design. The residence time may be adjusted accordingly which is known to strongly influence the extent of interaction between the plasma and wafer surface. Furthermore, the semiconductor wafer substrate may be exposed to plasma formed from various process gas compositions described herein. The gas composition or components thereof can be introduced into a plasma processing chamber and maintained at desired pressure ranges such as between approximately 1-15 torr. Selected gas flow rates may be further chosen to achieve desired gaseous mixtures ranging from approximately 100-15,000 sccm (for 200 mm wafer processing chambers). The process exposure time period may be modified according to the desired effect and the aforementioned variables. In addition, some embodiments of the invention may include connection of the processing chamber to a high vacuum source and a vacuum load-lock interface such as a two-stacked-chamber load-lock with transfer arm. Such equipment may involve a somewhat higher degree complexity and occupy more space beyond the wafer track system which can be integrated into an adjoining cassette end station (CES) area as illustrated in U.S. patent application Ser. No. 09/223,111 filed on Dec. 30, 1998, which is entitled Apparatus for Processing Wafers and herein incorporated by reference in its entirety. It shall be understood that these and other variables for configuring the plasma process chambers herein can be appropriately scaled for 300 mm wafer processing chambers and other desired applications.

The chemicals used in accordance with the invention herein are preferably non-toxic and environmentally friendly. As shown if FIG. 2, a controller 27 and a series of valves 23 or other mass transport devices can regulate the flow of a variety of gas sources 21 such as oxygen, helium, methane, hydrogen or other gases. These materials can offer easy and convenient effluent waste disposal procedures and handling unlike HMDS. The plasma deposited materials herein are relatively inexpensive and are readily commercially available from multiple sources. Furthermore these materials also have a relatively long shelf life and can be conveniently and inexpensively delivered to process chambers using mass flow controllers. No pumps or bubblers are required as with systems dispensing HMDS vapor. By controlling chemical ratios of plasma ingredients, different gaseous compositions can be selected to provide surface treatment and/or thin-film depositions. Moreover, a single set of gaseous chemicals may be provided in fact for all selected requirements with respect to surface priming and the formation of an anti-reflective coating. The wide variety of possible process variable alternatives and chemical formulations will become apparent to those of ordinary skill in the field and are encompassed within the scope of this disclosure. The examples herein are provided for illustrate purposes to explain the principles of this invention, and are not intended to limit its scope and breadth in any way.

Substrate Surface Modification

One aspect of the invention described herein provides a more ecological alternative to HMDS vapor prime treatments. For plasma surface prime applications, the invention can significantly reduce health risks and the likelihood of HMDS poisoning of chemically-amplified photoresists. One of the important objectives in forming a relatively hydrophobic region on a wafer is to modify its surface without adverse consequences to the photoresist coating formed thereon. During this surface modification treatment, a plasma can be introduced into a processing chamber in accordance with the invention to convert surface silanol groups, which are hydrophilic, into stable hydrophobic surfaces without detrimentally affecting desired integrated circuit film properties. The chemical bond energies associated with silanol groups are approximately as follows: (1) about 5.1 eV for the —O—H bond (which corresponds to the energy associated with 243 nm photons); and (2) about 5.8 eV for the —Si—O— bond. The —Si—O— bond is anomalously strong (e.g., the —C—H covalent bond strength in methane is about 4.5 eV), and therefore it is the hydrogen-to-oxygen bond in silanol that is the most susceptible to chemical interactions.

According to a preferable embodiment of the invention, a wafer surface may be exposed to a helium based plasma in a processing chamber 20 that is integrated within a wafer track system. Because of the relatively high energies associated with some of the proposed approaches herein, a particular substrate temperature may not be critical. In a preferable approach, wafer temperature during surface treatment would be similar to that generally used for vapor prime which is approximately 130-150° C. to primarily pre-dehydrate the wafer surface. The wafer surface can be (1) heated in a thermal module within a wafer track system prior to placement within a plasma processing chamber; (2) briefly exposed to a low-energy helium plasma; and (3) cooled on a chill plate prior to photoresist coating thereon. The wafer may however be preferably heated on a hot thermal plate within the plasma processing chamber before exposure to the helium plasma. The helium plasma formulation may include a relatively low concentration of methane ranging from approximately 0.5% to 5%, and may also optionally, include a relatively low concentration of hydrogen ranging from approximately 0.5% to 5%. The helium plasma accomplishes multiple objectives including the generation of vacuum ultraviolet radiation and the gentle bombardment of the wafer surface. In general, helium plasmas tend to be relatively very stable. Because of various factors including the relatively low atomic mass of helium, the plasma bombardment of the wafer surface is relatively gentle, and furthermore, the momentum transfer to the silanol hydrogen would tend to be relatively efficient because of the approximately matched masses therebetween.

In addition to helium, a relatively low concentration of methane may be added to provide highly reactive methylene free radicals as well as highly reactive methyl free radicals. A relatively low concentration of hydrogen can also provide most of the vacuum ultraviolet radiation emitted and inhibit the deposition of organic polymers on chamber walls. High frequency helium plasmas containing low concentrations of hydrogen are known to emit primarily hydrogen Lyman alpha radiation at 121.5 nm (generated by electronic transitions from the first electronic excited state of atomic hydrogen down to the ground electronic state), which corresponds to photon energy of 10.22 eV. These energetic photons can dissociate surface silanol groups. Such energetic vacuum ultraviolet photons can also efficiently chemically interact with (i.e., photolyze) methane, primarily producing methylene free radicals and molecular hydrogen:

CH₄+hv→CH₂+H₂*

where H₂* denotes molecular hydrogen in an excited state.

In addition to photolytic reaction, principal non-photolytic chemical reactions in such a gaseous plasma containing methane include:

CH₄→CH₃+H

CH₄→CH₂+H₂*

in addition to positively ionized species (negative ion formation by electron capture would occur with only negligible probabilities). CH₂(¹Σ) is known to be highly reactive to such an extent that methylene free radicals may be inserted intra-molecularly. Methylene free radicals may be able to react with silanol groups (inserting between the hydrogen and the oxygen) to form —Si—O—CH₃ groups resulting in hydrophobic surface groups. Furthermore, methyl free radicals (CH₃) may be able to heterogeneously combine with unstable —Si—O— surface dangling bonds to form hydrophobic —Si—O—CH₃ surface groups as well.

An optimal plasma gas composition can be formulated for selected applications in accordance with the invention as may be determined by specifically designed experimentation. Some relevant process variables and parameters include the following: plasma frequency (e.g., 400 kHz, 2.0 MHz, 13.56 MHz), plasma power (e.g., approximately 200-2000 watts), wafer temperature (may not be critical in the range of about 100-400° C.), process gas composition (including a single composition or a sequence of two or more compositions), process gas pressure and flow rate, showerhead-to-wafer spacing, process exposure time period. A preferable embodiment of the invention may be derived from such discretionary process variables including the following:

| Wafer temperature: | 100-400° C. (preferably 130-150° C.) | |
|---|---|---|
| Process gas: | 98% He/1% CH₄/1% H₂ | |
| Process pressure: | ˜3 | torr (˜400 Pascals) |
| Process gas flow rate: | ˜2000 | sccm |
| Showerhead-to-wafer spacing | ˜10 | mm |
| Plasma power: | 50-500 | W |
| Time period for plasma | ˜15 | sec. |
| exposure: | | |

A relatively low plasma power level may be sufficient for many vapor prime applications as described herein and is often preferred.

The plasma-based surface prime treatment and methodologies described herein provide numerous advantages over HMDS vapor prime treatment. These plasma formulations such as the described helium-based mixtures can replace the use of toxic HMDS which requires hazardous chemical handling and disposal procedures. In its place, a relatively non-toxic, non-flammable chemical is selected that is relatively easy to handle. Moreover, a proton acceptor chemical that would ordinarily prove a menace to deep UV photoresist development is substituted with a chemical that will not affect such development. A more robust process is also provided for development of a surface prime process that may help to suppress photoresist “footing.” Even further, plasma processing might provide opportunity for improving adhesion of 157 nm resists, which according to early indications, may otherwise tend to exhibit only marginally acceptable adhesion. These and other advantages of the invention significantly outweigh some measures of increased hardware complexity including the need for plasma generation reactors and equipment, and the need to provide an adequate vacuum environment such as available dry integrated point of use pumps (IPUPs) which are small and relatively inexpensive. Other additional considerations which should be accounted for with the plasma processing chambers herein include the need to prevent wafer sliding in vacuum, which may be addressed by the use of pins located at the wafer periphery capable of raising after the wafer is loaded.

It shall be understood that some additional experimentation may be performed with the surface prime treatments herein to achieve desired results. For example, regarding potential effects on integrated circuit film properties, high vacuum-ultraviolet irradiances at the wafer position on the order of tenths of mW/cm² and integrated photon fluxes in the 10¹⁴ photons/cm² range are sufficient to induce radiation damage in typical transistor gate insulators, resulting in serious flatband voltage shifts. Elevated substrate temperature during irradiance ameliorates damage, but these and other process variables may be deliberately selected to avoid transistor gate insulator flatband voltage shifts and increased gate leakage (transistor gate leakage is a problem for new generation ultra-thin gate insulator films in any event). Iterative multi-variable designs of experiments can be employed to optimize wafer surface prime treatment process parameters regarding key applicable process variables. A variety of wafer types may be selected in evaluating desirable process parameter. Wafer surface prime treatment evaluation steps, most of which can be performed using commercially available low resistivity p++ wafers with thin (˜15 nm) thermally-grown oxide, include: (1) water droplet wetting angle; (2) spin-on film adhesion; (3) electron spectroscopy for chemical analysis (ESCA), an analytical chemical examination of the wafer surface; (4) C-V measurements to look for possible flat-band voltage shifts using a C-V mercury probe; and (5) gate leakage characterization using wafers and electrical testing. Other technology development may include processes using only exposure to short wavelength ultraviolet radiation (without direct plasma exposure) that can be evaluated in parallel. Such processes would expose the wafer surface to short wavelength ultraviolet radiation through a window transparent to the wavelengths of interest. The shortest wavelengths (e.g., the 123.6 nm resonance radiation line of krypton, which approximates hydrogen Lyman alpha radiation) could be transmitted through a lithium fluoride window, intermediate UV wavelengths through calcium fluoride or magnesium fluoride windows, and longer UV wavelengths through very pure fused silica windows. The environment in contact with the wafer surface could be vacuum, helium, or, analogously with the plasma processes described above, low pressure methane or methane/hydrogen. For the case of a gaseous environment containing methane for which the radiation is absorbed by the methane, the light source may need to be placed relatively close to the wafer surface because light intensity would fall off exponentially for increasing distance from the light source. Also, illumination may need to be fairly uniformly distributed over the wafer surface. Process constancy risks include decreasing UV radiance reaching the wafer level due to darkening of the window and/or deposits on the window. These and other design factors may be balanced against an overall objective in integrating the plasma processing chambers herein into wafer tracks which can be a major and possibly an overriding consideration.

PECVD BARC Module

A variety of plasma-enhanced chemical vapor deposition (PECVD) applications are provided for bottom anti-reflective coating (BARC) processes in accordance with another aspect of the invention. These plasma processes provide highly conformal coatings which result in improved critical dimension (CD) control. By controlling the mixture of plasma constituents, the invention can provide customized “dial-in” anti-reflection properties. This aspect of the invention provides an advantage in being able to dial-in or design formulations with desired optical constants (e.g., refractive indices, extinction coefficients at exposure wavelengths) from a widely-available and easy-to-handle non-toxic gaseous chemical source(s). For example, the BARC films may be comprised of partially conjugated polyene structures. Even further, it is possible to plasma-deposit films with optical constants tailored as a function of depth into the film. Films with properly graded optical constants (or even films with suitable multiply-stepped optical constants) can provide improved anti-reflection characteristics than films with uniform optical constants. Graded optical constant films could be deposited by means of controlled, gas composition as the films are deposited, which may require at least two separate mass-flow controlled gas supply sources. An embodiment of the invention includes a preferable gas formulation for organic BARC deposition comprising about 25-75% acetylene (C₂H₂), 0-50% allene (CH₂CCH₂) and 25-75% carbon dioxide (CO₂). Other ratios and percentages of these constituents may be selected for certain applications in accordance with the invention.

As with other plasma processing chambers 20 described herein, it is possible to develop apparatus and processes that can be integrated with wafer tracks to permit plasma-enhanced deposition of BARC films. An even more preferable and space-saving embodiment of the invention includes a plasma chamber that can be also configured to carry out wafer surface prime treatment as described herein and/or BARC deposition. The plasma chamber may occupy an approximately six-inch region within a stack of thermal modules within the wafer track. Thus, a convenient and improved plasma processing module can be incorporated into an existing wafer track system to further provide vapor prime wafer surface treatment in place of a module or stand-alone equipment solely dedicated to performing spin-on BARC. In the event BARC deposition by itself can eliminate the need for prior wafer surface prime treatment, the functionality of the multi-purpose chamber is retained. The invention offers a choice of either wafer surface prime treatment and/or BARC PECVD, including a continuing option for convenient conversion of a previously selected wafer surface prime treatment to be upgraded to include BARC PECVD capabilities. Furthermore, PECVD BARC tends to give substantially better feature definition than spin-on BARC. Other advantages provided by the plasma-enhanced processing herein further include the elimination of an additional post-deposition high temperature hot plate bake step as with many current spin-on BARC techniques. A preferable method of BARC deposition may comprise the following steps: introducing a semiconductor wafer into a plasma chamber 20 positioned within a stack of modules within a wafer track environment; exposing the semiconductor wafer to a plasma to effect a wafer processing procedure such as BARC deposition; and heating the semiconductor wafer on a hot plate thereafter. Following each organic PECVD BARC film deposition, a deposition chamber cleaning step may be preferably carried out using an oxygen plasma to clean deposits from within the deposition chamber. Oxygen plasma may be easier and less expensive to implement than the process employed for inorganic BARC, which requires fluorine-based deposition chamber clean).

The BARC plasma deposition chambers provided in accordance with the invention can deposit films with excellent film thickness and optical constant uniformity. These demands can be especially demanding for 300 mm wafers applications which often require excellent showerhead designs in performing both optimum gaseous chemical precursor distribution over the wafer surface and uniform plasma power application in order to engender high area deposited film thickness uniformity. BARC process development may require a suitable metrology tool such as a spectral ellipsometer manufactured commercially by n&k Technology, Inc. (Santa Clara, Calif.) or Sopra (Westford, Mass.).

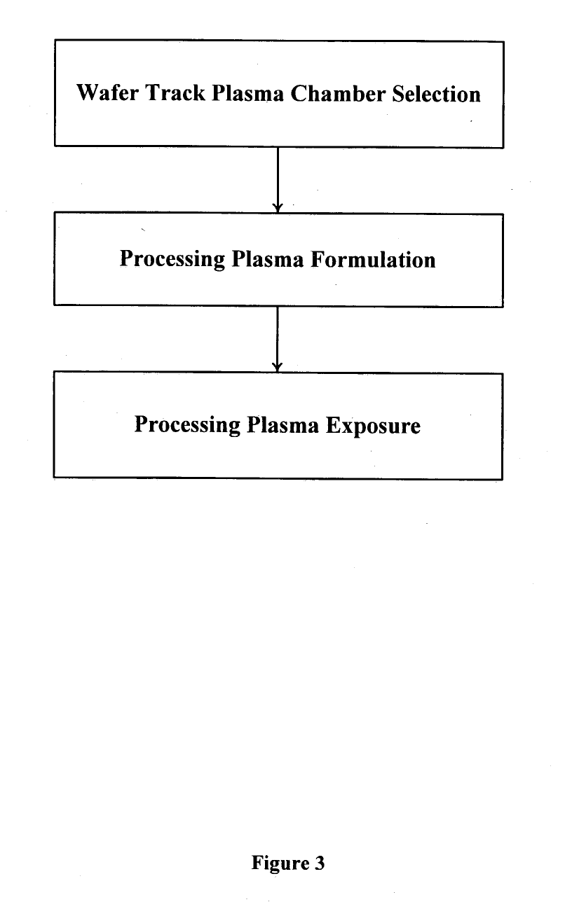

Another aspect of the invention provides various methods for processing semiconductor wafers or substrates within a wafer track environment. As illustrated in FIG. 3, a wafer processing procedure such as a surface prime treatment can be carried out by initially selecting a plasma processing chamber 20 such as those described herein. The processing chamber can be configured for placement within the thermal stack of a wafer track processing station or cell. A wafer may be positioned within the chamber and rest on a hot plate located therein to heat the wafer to a desired substrate temperature or range. The chamber may be also evacuated at the same time or after heating. A plasma derived from a preselected mix of gaseous materials such as helium can be generated and subsequently introduced into the processing chamber. A variety of mass transport control devices and conduits may be selected to regulate the combination of gases. The gases can be ionized by a plasma-generating device such as a parallel-plate showerhead electrode assembly within the processing chamber. A semiconductor wafer surface within the processing chamber may be thereafter exposed to the plasma to effect surface prime treatment or other desired surface modification. The gas flow and/or the flow of plasma may be terminated following desired surface treatment. The process chamber may be brought back to normal atmospheric pressure before removal of the treated semiconductor wafer or substrate.

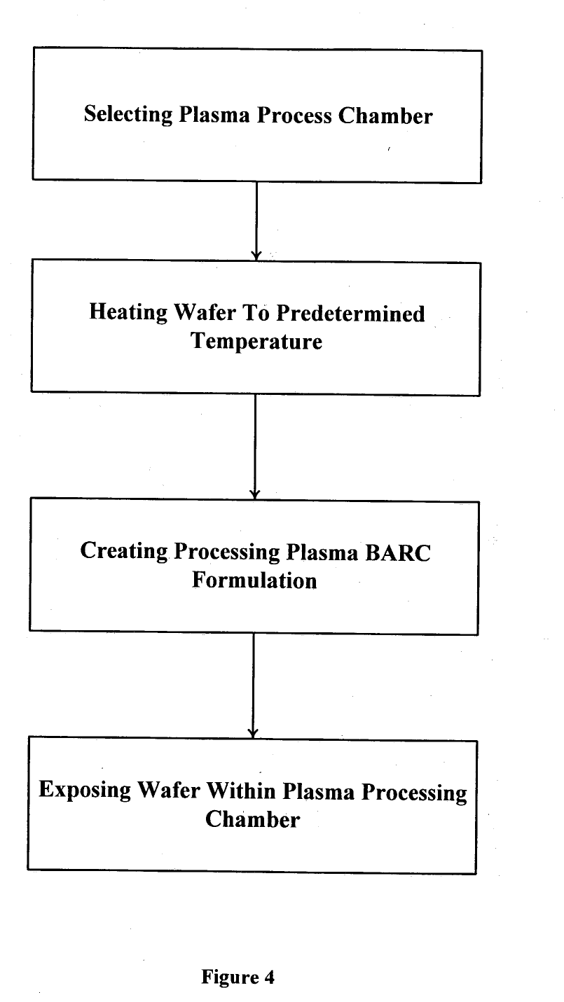

FIG. 4 describes yet another embodiment of the invention that provides a methods for depositing BARC films or coatings. A wafer track plasma processing chamber 20 may be initially selected as described herein to perform BARC deposition. The semiconductor wafer can be heated within the same chamber on a hot plate to complete the BARC deposition process. A variety of gaseous materials such as acetylene, allene and carbon dioxide can be then selected to achieve desired optical properties. The gas formulation may be ionized subsequently to form an organic BARC processing plasma that reacts with an exposed semiconductor wafer surface within the processing chamber. It shall be understood that these and other methodologies described herein may be combined and/or substituted to achieve desired results.

While the invention has been described with reference to the aforementioned specification, the descriptions and illustrations of the preferable embodiments herein are not meant to be construed in a limiting sense. It shall be understood that all aspects of the invention are not limited to the specific depictions, configurations or relative proportions set forth herein which depend upon a variety of conditions and variables. Various modifications in form and detail of the embodiments of the invention, as well as other variations of the invention, will be apparent to a person skilled in the art upon reference to the present disclosure. It is therefore contemplated that the appended claims shall also cover any such modifications, variations or equivalents.

What is claimed is:

1. A method of implementing wafer surface prime treatment comprising the following steps of:
selecting a plasma processing chamber within a wafer track system for exposing a semiconductor wafer surface to a processing plasma therein;
generating the processing plasma from a selected gaseous formulation for exposure to the semiconductor wafer surface; and
exposing the processing plasma to the semiconductor wafer surface to carry out wafer surface prime treatment.

2. The method as recited in claim 1, wherein the selected gaseous formulation comprises approximately 98% helium, 1% methane and 1% hydrogen.

3. A method for performing bottom anti-reflection coating (BARC) deposition comprising the following steps of:
selecting a plasma processing chamber within a wafer track system configured for plasma-enhanced chemical vapor deposition;
heating the semiconductor wafer to a predetermined temperature;
creating a processing plasma BARC formulation to be introduced into the plasma processing chamber; and
exposing a semiconductor wafer positioned within the plasma processing chamber to the processing plasma BARC formulation to deposit an anti-reflective coating onto the semiconductor wafer.

4. The method as recited in claim 3 wherein the BARC formulation provides an organic BARC film characterized by system-programmable optical constants for high-area uniformity.

5. A plasma chamber for performing semiconductor wafer processing comprising:
a processing chamber configured within a wafer track system for exposing a semiconductor wafer surface to a processing plasma;
a showerhead electrode and wafer chuck assembly positioned within the processing chamber for effecting plasma-enhanced processing of the semiconductor wafer; and
a plurality of supply gas sources in fluid communication with the showerhead electrode within the processing chamber that are regulated by a controller and a series of gas control valves to provide a preselected gaseous mixture, and wherein the gaseous mixture can pass through the showerhead electrode to generate the processing plasma that is exposed to the semiconductor wafer surface.

6. The plasma chamber as recited in claim 5, wherein the preselected gaseous mixture is applied for wafer surface prime treatment.

7. The plasma chamber as recited in claim 5, wherein the preselected gaseous mixture is applied for BARC deposition.
